(19) United States
(12) Patent Application Publication
(10) Pub. No.: US 2016/0351718 A1
(43) Pub. Date: Dec. 1, 2016

(54) METHOD FOR MANUFACTURING THIN FILM TRANSISTOR SUBSTRATE

(71) Applicant: HON HAI PRECISION INDUSTRY CO., LTD., New Taipei (TW)

(72) Inventors: CHIN-YUEH LIAO, New Taipei (TW); CHIA-LIN LIU, New Taipei (TW); YAN-TANG DAI, New Taipei (TW); HUNG-CHE LU, New Taipei (TW)

(21) Appl. No.: 14/838,040

(22) Filed: Aug. 27, 2015

(30) Foreign Application Priority Data
May 29, 2015 (TW) 104117270

(51) Int. Cl. H01L 29/786; H01L 27/12; H01L 29/45; G02F 1/1368

(52) U.S. Cl. CPC H01L 29/78603; G02F 1/1368; H01L 27/1288; H01L 27/124; H01L 27/1225; H01L 27/1222; H01L 29/7869; H01L 29/78669; H01L 29/78678; H01L 29/45

(57) ABSTRACT

A method for manufacturing an electronic substrate includes providing a substrate and forming a buffer layer on the substrate. A connection pad is formed on the buffer layer. An electrically insulating layer is formed on the buffer layer. A connection hole is defined in the electrically insulating layer. A connection line made of metal is formed on the electrically insulating layer and extends into the connection hole to electrically couple with the connection pad. An electrically insulating cover is formed on the electrically insulating layer to cover the connection line. A light irradiation is applied to the electrically insulating cover through a mask which has a first translucent region located corresponding to the connection line and a second translucent region located beside the connection line. A transmittance of the first translucent region is lower than a transmittance of the second translucent region.

### CROSS-REFERENCE TO RELATED APPLICATIONS

This application claims priority to Taiwan Patent Application No. 104117270 filed on May 29, 2015, the contents of which are incorporated by reference herein.

### FIELD

The subject matter herein generally relates to a thin film transistor liquid crystal display (TFT LCD), and in particular to a method for manufacturing a thin film transistor substrate for the TFT LCD.

### BACKGROUND

A TFT LCD includes a TFT substrate, a color filter over the TFT LCD and a liquid crystal layer between the TFT substrate and the color filter. By controlling rotations of liquid crystals in the liquid crystal layer by the TFT substrate, a picture can be displayed through the color filter. The TFT substrate includes electronic components such as thin film transistors, capacitors, connection pads and connection lines. After the electronic components are formed, an electrically insulating cover is formed to cover the electronic components. Thereafter, the electrical insulating cover is subjected to light exposure through a mask. The light exposure causes the electrically insulating cover to have a rugged top surface after development, which adversely affects a performance and reliability of the TFT substrate.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a flowchart showing a method for manufacturing a TFT substrate in accordance with a first embodiment of the present disclosure.

FIG. 2 is a cross-sectional view of a part of a TFT substrate corresponding to a first block of the method of FIG. 1.

FIG. 3 is a cross-sectional view of a part of a TFT substrate corresponding to a second block of the method of FIG. 1.

FIG. 4 is a cross-sectional view of a part of a TFT substrate corresponding to a third block of the method of FIG. 1.

FIG. 5 is a cross-sectional view of a part of a TFT substrate corresponding to a fourth block of the method of FIG. 1.

FIG. 6 is a cross-sectional view of a part of a TFT substrate corresponding to a fifth block of the method of FIG. 1.

FIG. 7 is a flowchart showing a method for manufacturing a TFT substrate in accordance with a second embodiment of the present disclosure.

FIG. 8 is a cross-sectional view of a part of a TFT substrate corresponding to a first block of the method of FIG. 7.

FIG. 9 is a cross-sectional view of a part of a TFT substrate corresponding to a second block of the method of FIG. 7.

FIG. 10 is a cross-sectional view of a part of a TFT substrate corresponding to a third block of the method of FIG. 7.

FIG. 11 is a cross-sectional view of a part of a TFT substrate corresponding to a fourth block of the method of FIG. 7.

FIG. 12 is a cross-section view of a part of a TFT substrate corresponding to a fifth block of the method of FIG. 7.

FIG. 13 is a cross-sectional view of a part of a TFT substrate corresponding to a sixth block of the method of FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

The present disclosure is described in relation to a method for manufacturing a TFT substrate.

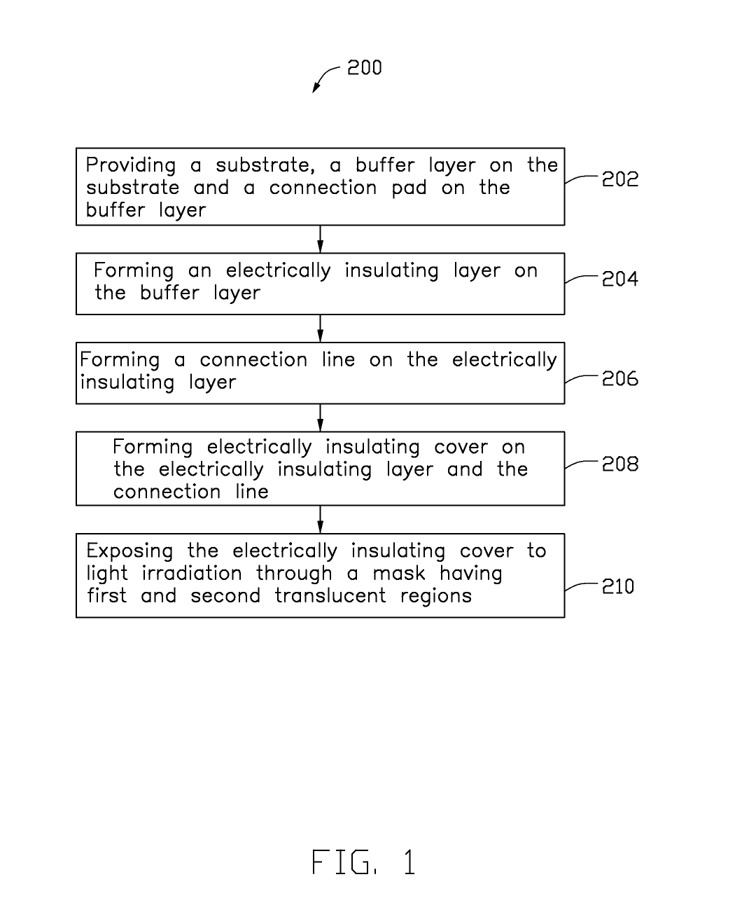

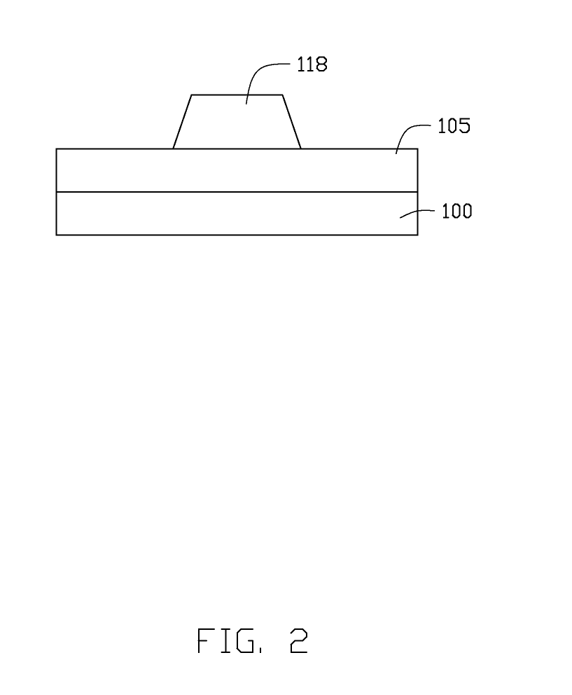

Referring to FIG. 1, a flowchart is presented in accordance with an example embodiment. The example method 200 is provided by way of example, as there are a variety of ways to carry out the method. The method 200 described below can be carried out using the configurations illustrated in FIGS. 2-6, for example, and various elements of these figures are referenced in explaining example method 200. Each block shown in FIG. 1 represents one or more processes, methods or subroutines, carried out in the example method 200. Furthermore, the illustrated order of blocks is illustrative only and the order of the blocks can change according to the present disclosure. Additional blocks can be added or fewer blocks may be utilized, without departing from this disclosure. The example method 200 can begin at block 202.

Also referring to FIG. 2, at block 202, a substrate 100 is provided. A buffer layer 105 is formed on the substrate 100, and a connection pad 118 is formed on the buffer layer 105. Although only one connection pad 118 is shown in FIG. 2, it can be understood that in reality there is a plurality of connection pads 118 formed on the substrate buffer layer 105.

In more detail, block 202 includes forming the buffer layer 105 on the substrate 100 and then forming a metal layer on the buffer layer 105. The metal layer is then patterned through photolithography under a yellow light environment to form the connection pad 118.

According to this embodiment, the substrate 100 can be made of transparent material such as glass, quartz or organic polymer. The buffer layer 105 can be made of transparent, electrically insulating material such as silicon oxide, silicon nitride, or silicon oxide nitride. The connection pad 118 can be made of metal such as aluminum, titanium, molybdenum, tantalum, or copper. It can be understood that the buffer layer 105 can be omitted; then the connection pad 118 is directly formed on the substrate 100.

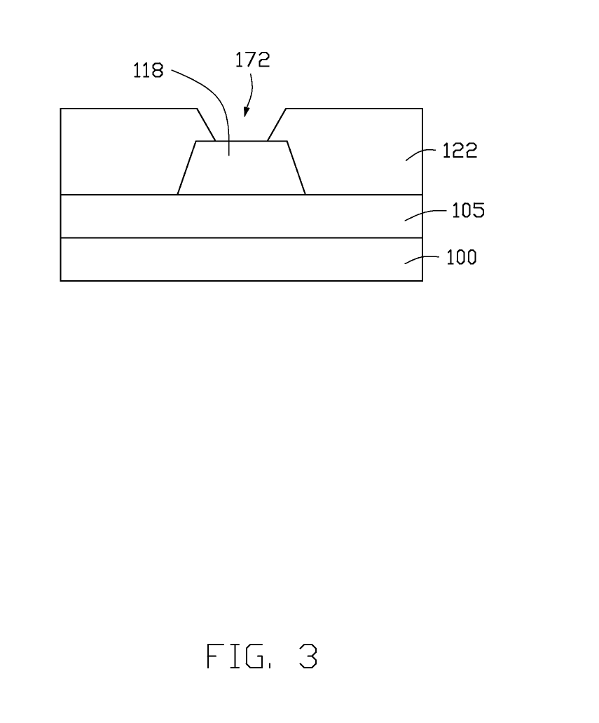

Also referring to FIG. 3, at block 204, an electrically insulating layer 122 is formed to cover the buffer layer 105 and the connection pad 118. A connection hole 172 is defined in electrically insulating layer 122 at a position corresponding to the connection pad 118 whereby the connection pad 118 is exposed through the connection hole 172. The connection hole 172 is formed through photolithography to the electrically insulating layer 122 in a yellow light environment.

In this embodiment, the electrically insulating layer 122 can be made of transparent, insulating material such as aluminum oxide, silicon oxide, silicon nitride or silicon oxide nitride.

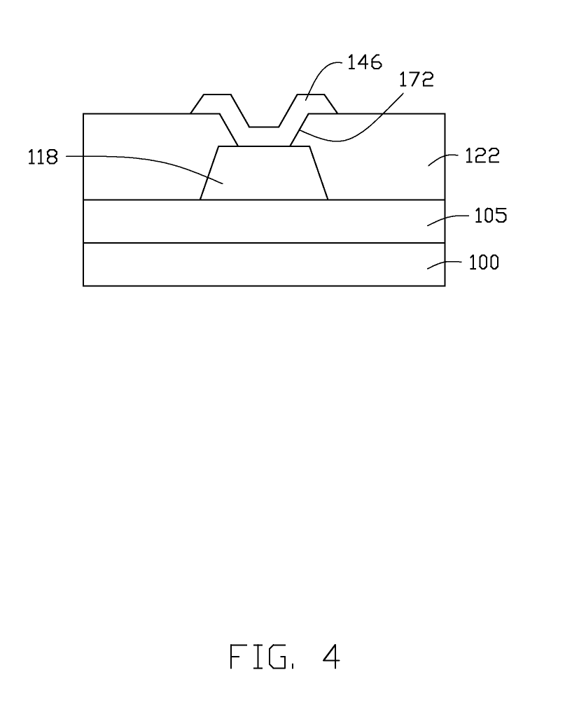

Also referring to FIG. 4, at block 206, a connection line 146 is formed on the electrically insulating layer 122. The connection line 146 extends through the connection hole 172 to electrically connect with the connection pad 118. In this embodiment, the connection line 146 is formed by firstly applying a metal layer on the electrically insulating layer 122. Then the metal layer is processed by photolithography under a yellow light environment to form the connection line 146. The connection line 146 occupies an area which is larger than an area occupied by the connection pad 118. The connection line 146 can be made of aluminum, titanium, molybdenum, tantalum, or copper which can reflect light impinges thereon.

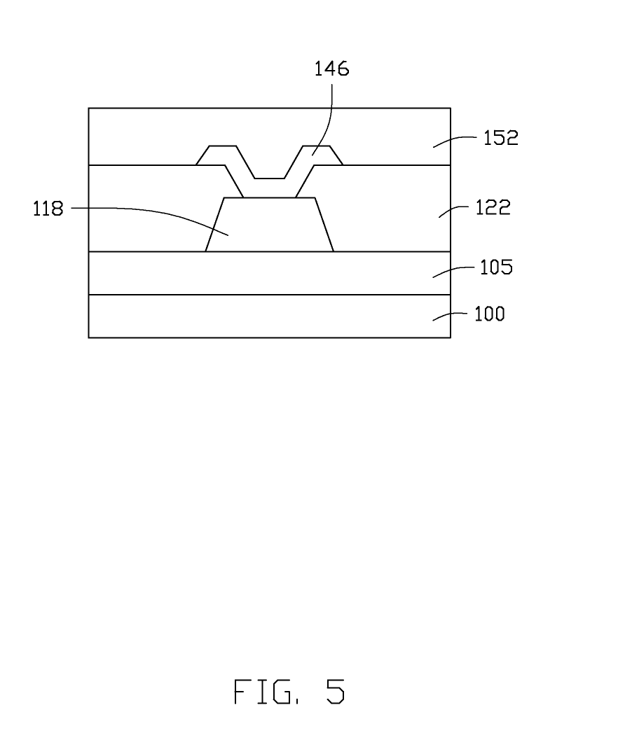

Also referring to FIG. 5, at block 208, an electrically insulating cover 152 is formed on the electrically insulating layer 122 and the connection line 122. The electrically insulating cover 152 is a passivation layer and can be made of organic material such as polycarbonate (PC) or benzocyclobutene (BCB).

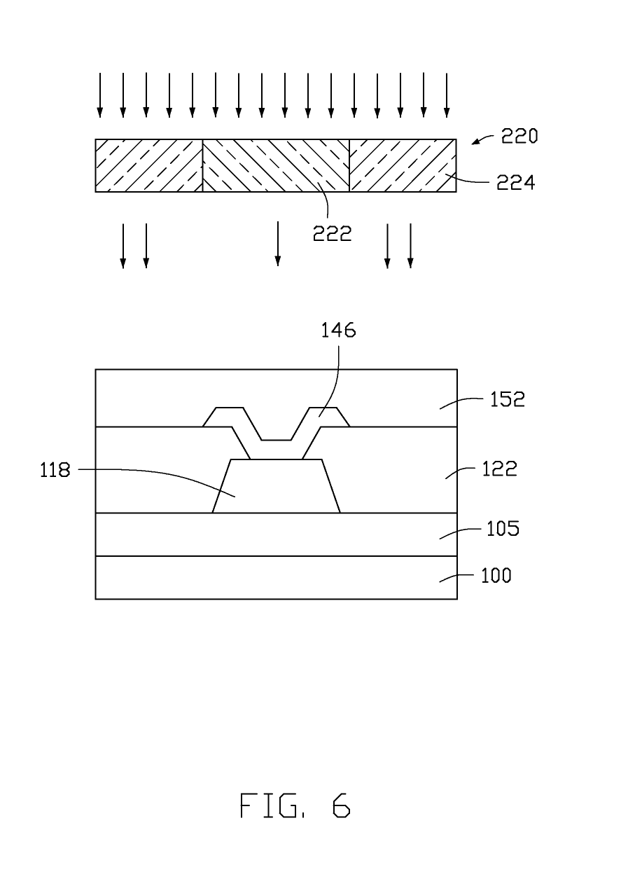

Also referring to FIG. 6, at block 210, the electrically insulating cover 152 is exposed to light irradiation, for example, ultraviolet light irradiation, through a mask 220. The mask 220 has a first translucent region 222 located corresponding to a region of the electrically insulating cover 152 in which the connection line 146 is formed, and a second translucent region 224 located corresponding to a region of the electrically insulating cover 152 beside the connection line 146. A transmittance of the first translucent region 222 is lower than a transmittance of the second translucent region 224. The first translucent region 222 can have a transmittance between 5% and 90%. Moreover, the first translucent region 222 can have a transmittance between 20% and 80%. The second translucent region 224 can have a transmittance which is 5%-10% more than that of the first translucent region 222. For example, when the first translucent region 222 has a transmittance of 20%, the second translucent region 224 has a transmittance of 25%-30%.

After being irradiated by light which can be ultraviolet light, a photoresist developer (not shown) is used to develop the electrically insulating cover 152. The region of the electrically insulating cover 152 corresponding to the second translucent region 224 of the mask 220 is passivated to increase its transmittance. The region of the electrically insulating cover 152 corresponding to the first translucent region 222 of the mask 220 has less light irradiated thereon. Accordingly, even when the connection line 146 is made of metal and can reflect light impinging thereon, there is no intensive light reflected by the connection line 146 through a part of the electrically insulating cover 152 above the connection line 146. Thus no overexposure to light irradiation will happen to the electrically insulating cover 152 at a position thereof corresponding to the connection line 146, whereby a depression in a top face of the electrically insulating cover 152 over the connection line 146 can be avoided after the electrically insulating cover 152 is developed by the photoresist developer. Thus, the top face of the electrically insulating cover 152 can be prevented from being rugged, but be kept flat and smooth to ensure the reliability and performance of the TFT substrate.

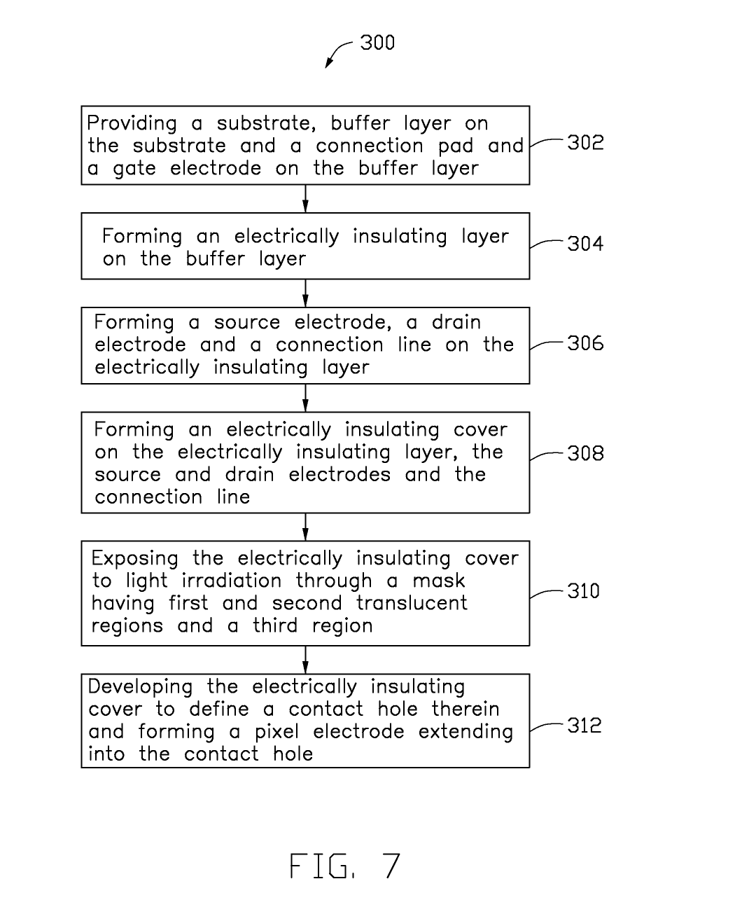

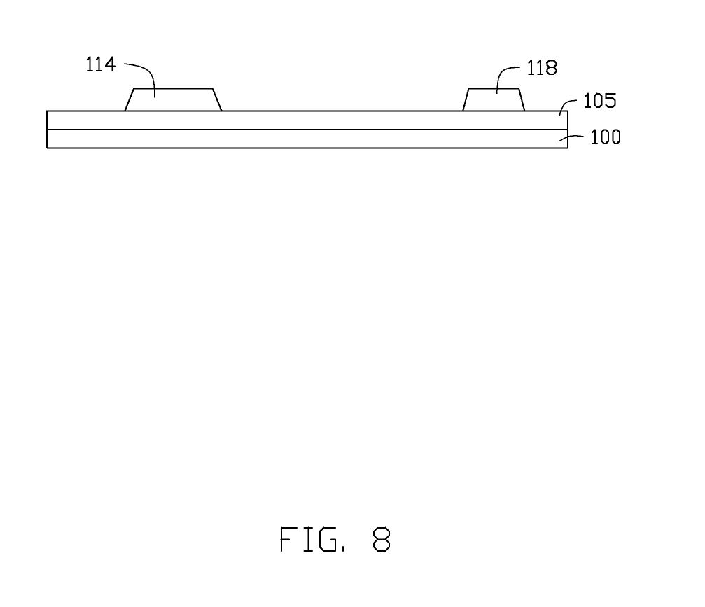

Referring to FIG. 7, a flowchart is presented in accordance with another example embodiment. The example method 300 is provided by way of example, as there are a variety of ways to carry out the method. The method 300 described below can be carried out using the configurations illustrated in FIGS. 8-13, for example, and various elements of these figures are referenced in explaining example method 300. Each block shown in FIG. 7 represents one or more processes, methods or subroutines, carried out in the example method 300. Furthermore, the illustrated order of blocks is illustrative only and the order of the blocks can change according to the present disclosure. Additional blocks can be added or fewer blocks may be utilized, without departing from this disclosure. The example method 300 can begin at block 302.

Also referring to FIG. 8, at block 302, a substrate 100 is provided. Then a buffer layer 105 is formed on the substrate 100 and a gate electrode 114 and a connection pad 118 are formed on the buffer layer 105. The gate electrode 114 and the connection pad 118 are formed by first applying a metal layer on the buffer layer 105 and then processing (i.e., patterning) the metal layer by photolithography under a yellow light environment. Although only one gate electrode 114 and one connection pad 118 are shown in FIG. 8, it can be understood that in fact there are a plurality of gate electrodes 118 and connection pads 114 formed on the buffer layer 105.

According to this embodiment, the substrate 100 can be made of transparent material such as glass, quartz, or organic polymer. The buffer layer 105 can be made of transparent, electrically insulating material such as silicon oxide, silicon nitride, or silicon oxide nitride. The gate electrode 114 and the connection pad 118 can be made of metal such as aluminum, titanium, molybdenum, tantalum, or copper. It can be understood that the buffer layer 105 can be omitted, whereby the gate electrode 114 and the connection pad 118 are directly formed on the substrate 100.

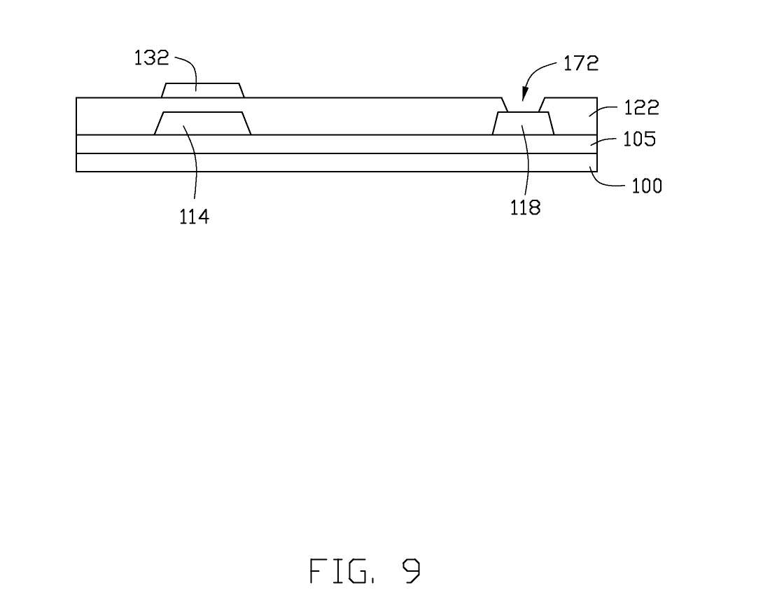

Also referring to FIG. 9, at block 304, an electrically insulating layer 122 is formed to cover the buffer layer 105, the gate electrode 114 and the connection pad 118. A channel layer 132 is formed on the electrically insulating layer 122 at a location corresponding to the gate electrode 114. A connection hole 172 is defined in the electrically insulating layer 122 at a location corresponding to the connection pad 118 whereby the connection pad 118 is exposed through the connection hole 172.

To form the channel layer 132 and the connection hole 172, first a semiconductor layer is applied on the electrically insulating layer 122. Then the semiconductor layer is processed by photolithography under a yellow light environment to form the channel layer 132. The photolithography also patterns the electrically insulating layer 122 to form the connection hole 172.

According to this embodiment, the electrically insulating layer 122 can be made of transparent, electrically insulating material such as aluminum oxide, silicon oxide, silicon nitride or silicon oxide nitride. The channel layer 132 can be made of semiconductor material such as metal oxide, amorphous silicon, or polycrystalline silicon (also called polysilicon).

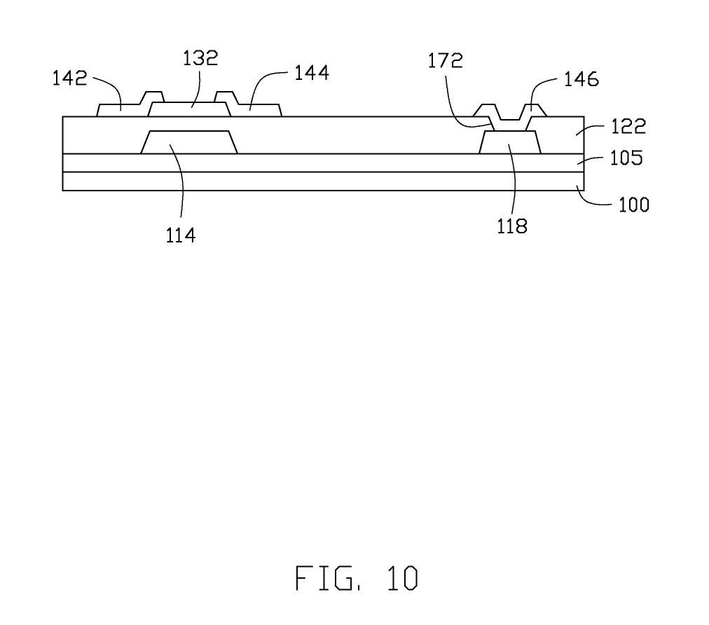

Also referring to FIG. 10, at block 306, a source electrode 142, a drain electrode 144 and a connection line 146 are formed on the electrically insulating layer 122. The source electrode 142 and the drain electrode 144 are formed on the electrically insulating layer 122 over two opposite ends of the channel layer 132 whereby the source and drain electrodes 142, 144 are electrically coupled with the channel layer 132. The connection line 146 is formed on the electrically insulating layer 122 and extends downwardly thorough the connection hole 172 to electrically couple with the connection pad 118. The connection line 146 occupies a real estate larger than a real estate occupied by the connection pad 118. An area occupied by the channel layer 132, the source electrode 142 and the drain electrode 144 in combination is larger than an area occupied by the gate electrode 114. The source and drain electrodes 142, 144 and the connection line 146 are formed by first applying a metal layer on the electrically insulating layer 122 and then processing the metal layer by photolithography. The source and drain electrodes 142, 144 and the connection line 146 can be made of metal such as aluminum, titanium, molybdenum, tantalum, or copper.

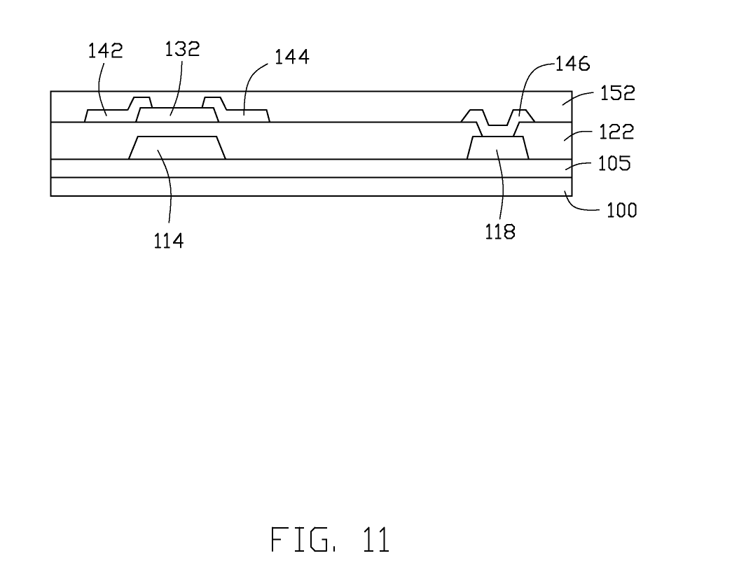

Also referring to FIG. 11, at block 308, an electrically insulating cover 152 is formed to cover the source electrode 142, the channel layer 132, the drain electrode 144, the connection line 146 and the electrically insulating layer 122. The electrically insulating cover 152 is a passivation layer and can be made of organic material such as polycarbonate (PC) or benzocyclobutene (BCB).

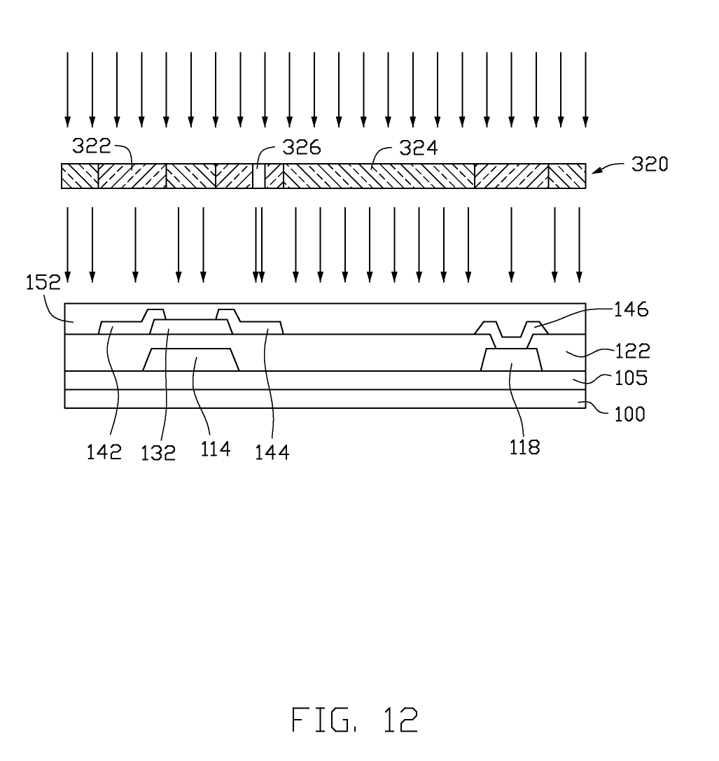

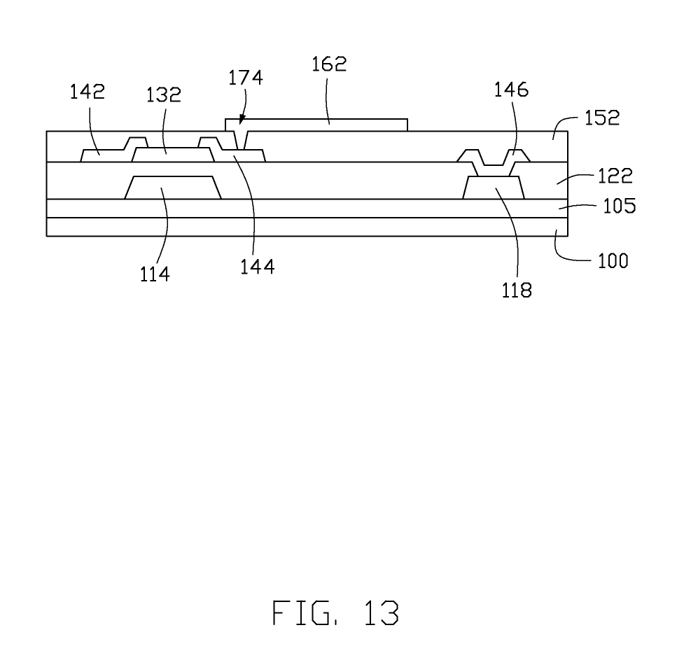

Also referring to FIG. 12, at block 310, the electrically insulating cover 152 is exposed to light irradiation through a mask 320. The mask 320 has a first translucent region 322 located corresponding to a region of the electrically insulating cover 152 in which the connection line 146, the source electrode 142 and the drain electrode 144 are formed, and a second translucent region 324 located corresponding to a region of the electrically insulating cover 152 beside the connection line 146, the source electrode 142 and the drain electrode 144. The mask 320 further has a third region 326 located corresponding to a part of the electrically insulating cover 152 in which a foot portion of the drain electrode 144 is formed. The third region 326 is used for forming a contact hole 174 (FIG. 13) in the electrically insulating cover 152. A transmittance of the second translucent region 324 is lower than a transmittance of the third region 326, while a transmittance of the first translucent region 322 is lower than that of the second translucent region 324. The first translucent region 322 can have a transmittance between 5% and 90%. Moreover, the first translucent region 322 can have a transmittance between 20% and 80%. The second translucent region 324 can have a transmittance which is 5%-10% more than that of the first translucent region 322. The third region 326 can have a transmittance of 100%. In other words, the third region 326 can be transparent.

After being irradiated by light which can be ultraviolet light, the part of the electrically insulating cover 152 which corresponds to the third region 326 and can absorb the highest intensity of light irradiation can be removed by a photoresist developer (not shown) to define the contact hole 174 (FIG. 13). The region of the electrically insulating cover 152 corresponding to the second translucent region 324 of the mask 320 is passivated to increase its transmittance. The region of the electrically insulating cover 152 corresponding to the first translucent region 322 of the mask 320 has less light irradiated thereon since the first translucent region 322 has the least transmittance. Accordingly, even that the connection line 146, the source electrode 142 and the drain electrode 144 which are made of metal and can reflect light impending thereon, there is no intensive light reflected by the connection line 146, the source electrode 142 and the drain electrode 144, whereby a rugged top face of the electrically insulating cover 152 over the connection line 146, the source electrode 142 and the drain electrode 144 due to an overexposure thereof to the light irradiation can be avoided by the present disclosure after the electrically insulating cover 152 is developed by the photoresist developer (not shown). Thus, the top face of the electrically insulating cover 152 can be kept flat and smooth to ensure the performance and reliability of the TFT substrate.

Also referring to FIG. 13, at block 312, the photoresist developer (not shown) is applied to the top face of the electrically insulating cover 152 after the electrically insulating cover 152 has been subjected to the light irradiation through the mask 320. By the photoresistor developer, the contact hole 174 is formed in the electrically insulating cover 152 to expose the foot portion of the drain electrode 144. Then, a pixel electrode 162 is formed on the electrically insulating layer 152 and extends into the contact hole 174 to electrically couple with the drain electrode 144. The pixel electrode 162 is formed by applying a transparent, electrically conductive layer on the electrically insulating cover 152 and then patterning the transparent, electrically conductive layer by photolithography to obtain the pixel electrode 162. The pixel electrode 162 can be made of indium tin oxide (ITO).

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size and arrangement of parts within the principles of the present disclosure, up to and including the full extent established by the broad general meaning of the terms used in the claims.

What is claimed is:

1. A method for manufacturing an electronic substrate comprising:
providing a substrate and forming at least one first electrically conductive component on the substrate;
forming an electrically insulating layer on the substrate to cover the at least one first electrically conductive component;
defining at least one connection hole in the electrically insulating layer to expose the at least one first electrically conductive component;
forming at least one second electrically conductive component on the electrically insulating layer, the at least one second electrically conductive component extending into the at least one connection hole to electrically couple with the at least one first electrically conductive component, the at least one second electrically conductive component being light reflective;
forming an electrically insulating cover on the electrically insulating layer to cover the at least one second electrically conductive component;
irradiating the electrically insulating cover with light through a mask, the mask having a first translucent region located corresponding to the at least one second electrically conductive component and a second translucent region located beside the at least one second electrically conductive component, the first translucent region having a transmittance lower than a transmittance of the second translucent region; and
developing the electrically insulating cover by using a photoresist developer.

2. The method of claim 1, wherein the first translucent region has a transmittance between 5% and 90%.

3. The method of claim 2, wherein the first translucent region has a transmittance between 20% and 80%.

4. The method of claim 1, wherein the at least one first electrically conductive component is at least one connection pad and the at least one second electrically conductive component is at least one connection line, the at least one connection line being made of a metal selected from at least one of a group consisting of aluminum, titanium, molybdenum, tantalum, and copper.

5. The method of claim 4, wherein the substrate is made of transparent material selected from at least one of a group consisting of glass, quartz and organic polymer.

6. The method of claim 5, further comprising a step of forming a buffer layer on the substrate, the at least one first electrically conductive component and the electrically insulating layer being formed on the buffer layer, wherein the buffer layer is made of electrically insulating and transparent material selected from at least one of a group consisting of silicon oxide, silicon nitride and silicon oxide nitride.

7. The method of claim 6, wherein the electrically insulating layer is made of transparent, electrically insulating material selected from at least one of a group consisting of aluminum oxide, silicon oxide, silicon nitride or silicon oxide nitride.

8. The method of claim 6, wherein during the step of forming the at least one first electrically conductive component on the buffer layer, at least one gate electrode is also formed on the buffer layer.

9. The method of claim 8, wherein during the step of defining the at least one connection hole in the electrically insulating layer, at least one channel layer is also formed on the electrically insulating layer.

10. The method of claim 9, wherein during the step of forming the at least one second electrically conductive component on the electrically insulating layer, at least one source electrode and at least one drain electrode are also formed on the electrically insulating layer, the at least one source electrode and the at least one drain electrode electrically coupling with two opposite ends of the at least one channel layer, the first translucent region of the mask being located also corresponding to the at least one source electrode and the at least one drain electrode.

11. The method of claim 10, wherein the at least one channel layer is be made of semiconductor material selected from at least one of a group consisting of metal oxide, amorphous silicon, and polysilicon.

12. The method of claim 11, wherein the at least one source electrode and the at least one drain electrode are made of metal selected from at least one of a group consisting of aluminum, titanium, molybdenum, tantalum, and copper.

13. The method of claim 12, wherein the mask further has a third region which has a transmittance higher than the transmittance of the first translucent region and the transmittance of the second translucent region, the third region of the mask is located corresponding to at least a part of the at least one drain electrode.

14. The method of claim 13, wherein the electrically insulating cover is made of organic material selected from at least one a group consisting of polycarbonate and benzocyclobutene.

15. The method of claim 14, wherein at least one contact hole is defined in the electrically insulating cover after the step of developing the electrically insulating cover, the at least a part of the at least one drain electrode being exposed through the at least one contact hole.

16. The method of claim 15, further comprising forming at least one pixel electrode on the electrically insulating cover, the at least one pixel electrode extending into the at least one contact hole to electrically couple with the at least one drain electrode.

17. A method for forming a thin film transistor substrate comprising:
providing a substrate and forming a buffer layer on the substrate;
forming at least one connection pad and at least one gate electrode on the buffer layer;
forming an electrically insulating layer on the buffer layer to cover the at least one connection pad and the at least one gate electrode;
defining at least one connection hole in the electrically insulating layer to expose the at least one connection pad and forming at least one channel layer on the electrically insulating layer and over the gate electrode;
forming at least one source electrode, at least one drain electrode and at least one connection line on the electrically insulating layer, wherein the at least source and drain electrodes electrically connect with the at least one channel layer and the at least one connection line extends into the at least one connection hole to electrically couple with the at least connection pad, the at least one source and drain electrodes and the at least one connection line being made of metal;
forming an electrically insulating cover on the electrically insulating layer to cover the at least one source electrode, the at least one drain electrode, the at least one channel layer and the at least one connection line, the electrically insulating cover being made of polymer material;
irradiating the electrically insulating cover with light through a mask having a first translucent region, a second translucent region and a third region, a transmittance of the first translucent region being smaller than a transmittance of the second translucent region which is smaller than a transmittance of the third region, the first translucent region being located corresponding to the at least one connection line, the at least one source electrode and the at least one drain electrode, the second translucent region being located beside the at least one connection line, the at least one source electrode and the at least one drain electrode and the third region being located corresponding to a part of the at least one drain electrode;
developing the electrically insulating cover by a photoresist developer to define at least one contact hole in the electrically insulating cover, the part of the at least one drain electrode located corresponding to the third region during the step of irradiating the electrically insulating cover being exposed through the at least one contact hole; and
forming at least one pixel electrode on the electrically insulating cover, the at least one pixel electrode extending into the at least one contact hole to electrically couple with the at least one drain electrode.

18. The method of claim 17, wherein the at least one channel layer is made of semiconductor material selected from at least one a group consisting of metal oxide, amorphous silicon, and polysilicon.

19. The method of claim 18, wherein the at least one source and drain electrodes and the at least one connection line are made of metal selected from at least one of a group consisting of aluminum, titanium, molybdenum, tantalum, and copper.

20. A method for manufacturing an electronic substrate, the method comprising:
providing an electronic component including an electrically insulating layer on a substrate, at least one connection hole in the electrically insulating layer, at least one light reflective electrically conductive component on the electrically insulating layer extending into the at least one connection hole, and an electrically insulating cover on the electrically insulating layer to cover the at least one light reflective electrically conductive component;
providing a mask having a first translucent region and a second translucent region, the first region having a lower light transmittance than the second region;
aligning a mask with the insulating cover such that the first translucent region is aligned with the at least one light reflective electrically conductive component and the second translucent region is aligned adjacent the at least one light reflective electrically conductive component; and
irradiating the electrically insulating cover with light through the aligned mask;
wherein the lower transmittance of the first region limits the amount of right reaching the at least one light reflective second electrically conductive component, thereby limiting light reflection during manufacture of the electronic component.
